(19) United States
(12) Patent Application Publication
(10) Pub. No.: US 2011/0074753 A1
(43) Pub. Date: Mar. 31, 2011

(54) Display apparatus

(75) Inventors: Tetsuro Yamamoto, Kanagawa (JP); Katsuhide Uchino, Kanagawa (JP)

(73) Assignee: Sony Corporation, Tokyo (JP)

(21) Appl. No.: 12/923,107

(22) Filed: Sep. 2, 2010

(30) Foreign Application Priority Data
Sep. 25, 2009 (JP) 2009-220504

(51) Int. Cl. G09G 3/30; G09G 5/00

(52) U.S. Cl. 345/207; 345/76

(57) ABSTRACT

A display apparatus includes a pixel array that has pixel units arranged in a matrix on the basis of a predetermined array pattern, each pixel unit having a light emitting element formed therein and having a structure configured to emit light generated from the light emitting element. In the structure of the pixel unit, a photodetection element which allows a current to flow in response to received light is provided to correspond to an inner area of a light emitting layer which forms the light emitting element. The pixel unit has a light incidence structure configured to allow the light, which is generated from the light emitting element, to be incident to the photodetection element.

### BACKGROUND OF THE INVENTION

1. Field of the Invention

The present invention relates to a display apparatus using, for example, organic electroluminescence elements (an organic EL element).

2. Description of the Related Art

In active matrix display apparatuses using organic electroluminescence (EL: Electroluminescence) light emitting elements in pixels, the current, which flows to a light emitting element inside each pixel circuit, is controlled by an active element (generally, a thin film transistor: TFT) provided inside the pixel circuit. That is, since the organic EL is an electroluminescence element, grayscale for coloring is obtained by controlling the amount of current flowing to the EL element.

FIG. 16A shows an example of a pixel circuit using the organic EL element.

In addition, although only one pixel circuit is shown herein, in an actual display apparatus, the pixel circuits shown herein are arranged in a matrix, and each pixel circuit is selected and driven by a horizontal selector 11 and a write scanner 13.

The pixel circuit has a sampling transistor Ts formed by an n-channel TFT (Thin Film Transistor), a storage capacitor Cs, a driving transistor Td formed by a p-channel TFT, and an organic EL element 1. The pixel circuit is disposed at a crossing portion between a signal line DTL and a write control line WSL. The signal line DTL is connected to one end of the sampling transistor Ts, and the write control line WSL is connected to the gate of the sampling transistor Ts.

The driving transistor Td and the organic EL element 1 are connected in series between a power supply Vcc and a ground potential. Further, the sampling transistor Ts and the storage capacitor Cs are connected to the gate of the driving transistor Td. The voltage between the gate and the source of the driving transistor Td is represented by Vgs.

In the pixel circuit, when the write control line WSL is made to be in a selection state and a signal value is applied to the signal line DTL in response to a luminance signal, the sampling transistor Ts becomes conductive, and thus the signal value is written in the storage capacitor Cs. The electric potential of the signal value, which is written in the storage capacitor Cs, becomes equal to the electric potential of the gate of the driving transistor Td.

When the write control line WSL is made to be in a non-selection state, the signal line DTL is electrically disconnected from the driving transistor Td, but the electric potential of the gate of the driving transistor Td is stably held by the storage capacitor Cs. Then, driving current Ids flows from the power supply potential Vcc toward the ground potential through the driving transistor Td and the organic EL element 1.

At this time, since the current Ids becomes equal to a value corresponding to the voltage Vgs between the gate and the source of the driving transistor Td, the organic EL element 1 emits light with a luminance based on the level of the current Ids.

That is, in the case of the pixel circuit, by writing the electric potential of the signal, which is transmitted from the signal line DTL, in the storage capacitor Cs, the gate voltage of the driving transistor Td is changed. In such a manner, by controlling the current flowing to the organic EL element 1, the grayscale level is obtained.

The source of the driving transistor Td formed by the p-channel TFT is connected to the power supply Vcc, and is thus set to be continuously operated in the saturated region. Hence, for example, assuming that the threshold voltage of the driving transistor Td is Vth; the voltage between the gate and the source of the driving transistor Td is Vgs; and the voltage between the drain and the source of the driving transistor Td is Vds, the setting is made to satisfy the following condition: Vgs-Vth<Vds.

At this time, the current Ids, which flows between the drain and the source of the driving transistor Td, is represented by the following expression. Furthermore, in the following expression, [̂2] represents a power of two.

Ids=(½)μ(W/L)·Cox·(Vgs−Vgh)̂2 (Expression 1)

In the saturated region, in a condition where the gate-source voltage Vgs is constant, regardless of change of the drain-source voltage Vds, the current Ids does not change. That is to say, in the condition where the gate-source voltage Vgs is constant, the driving transistor Td is regarded as a constant current source.

Besides, even in the saturated region, the current Ids linearly changes in response to the gate-source voltage Vgs. That is, the driving transistor Td is operated in the saturated region, and subsequently the gate-source voltage Vgs is changed, thereby controlling the current Ids having an optional level so that it stably flows. Consequently, by controlling the gate-source voltage Vgs, it is possible to make the organic EL element 1 stably emit light at a desired luminance.

Here, FIG. 16B shows change in current-voltage (I-V) characteristics of the organic EL element with the elapse of time. The curve indicated by the solid line shows the characteristic in the initial condition, and the curve indicated by the dashed line shows the characteristics changed after the elapse of time. Generally, as shown in the drawing, the I-V characteristics of the organic EL element deteriorate as time passes. That is, even if the same voltage V is applied, as time passes, the current flowing to the organic EL element decreases. This means that the luminous efficiency of the organic EL element is lowered and deteriorated with the elapse of time.

The deterioration of the organic EL element causes, for example, burn-in as described below.

For example, as shown in FIG. 17A, it is assumed that the shape of a white window is displayed on a black screen during a certain period and thereafter the screen is changed into a full white screen again. Then, the luminance of the part, on which the window shape was displayed, is lowered, and the part is viewed as if it is darker than the surrounding white part. As a result, display unevenness is caused.

For example, Japanese Unexamined Patent Application Publication Nos. 2007-171507 and 2007-72305 discloses techniques for reducing and correcting the above-mentioned burn-in.

### SUMMARY OF THE INVENTION

The invention addresses the issue of correcting burn-in caused by deterioration of organic EL elements and acquiring an effect of more improved burn-in correction.

In view of the above-mentioned problem, according to an embodiment of the invention, a display apparatus is configured as follows.

That is, the display apparatus includes a pixel array that has pixel units arranged in a matrix on the basis of a predetermined array pattern, each pixel unit having a light emitting element formed therein and having a structure configured to emit light generated from the light emitting element. In the structure of the pixel unit, a photodetection element which allows current to flow in response to received light is provided to correspond to an inner area of a light emitting layer which forms the light emitting element. The pixel unit has a light incidence structure configured to allow the light, which is generated from the light emitting element, to be incident to the photodetection element.

In the above-mentioned configuration, the display apparatus is configured to have a pixel array in which the pixel units, each having the structure for emitting light generated from the light emitting element, are arranged in a matrix.

Besides, in each pixel unit, the photodetection element is provided, and the photodetection element is disposed to be vertically located in the area of the light emitting layer. Further, the pixel unit has a structure for allowing the light, which is generated from the light emitting element, to be incident to the photodetection element. With such a configuration, the photodetection element is able to more sensitively receive the light which is generated in the same pixel unit.

As described above, since the photodetection element is able to sensitively receive the light generated in the same pixel unit, it is possible to improve, for example, the effect of the burn-in correction and the like obtained by using the photodetection element.

### BRIEF DESCRIPTION OF THE DRAWINGS

FIG. 1 is a diagram illustrating an exemplary configuration of an organic EL display apparatus according to an embodiment;

FIGS. 2A and 2B are diagrams illustrating a configuration of a first example of a pixel circuit according to the embodiment;

FIG. 3 is a diagram illustrating a configuration of a second example of the pixel circuit according to the embodiment;

FIGS. 4A and 4B are diagrams illustrating a first example of a light incidence structure;

FIGS. 5A and 5B are diagrams illustrating a second example of the light incidence structure;

FIGS. 6A and 6B are diagrams illustrating a third example of the light incidence structure;

FIGS. 7A and 7B are diagrams illustrating a fourth example of the light incidence structure;

FIG. 8 is a diagram illustrating a fifth example of the light incidence structure;

FIG. 9 is a diagram illustrating a setting of a thickness of an EL layer according to the embodiment;

FIGS. 10A and 10B are diagrams illustrating an exemplary structure of an organic EL panel as a first example of a B-light blocking configuration;

FIGS. 11A and 11B are diagrams illustrating an exemplary structure of the organic EL panel as a second example of the B-light blocking configuration;

FIGS. 12A and 12B are diagrams illustrating an exemplary structure of the organic EL panel as a third example of the B-light blocking configuration;

FIG. 13 is a diagram illustrating another exemplary configuration of the organic EL display apparatus according to a modified example of the embodiment;

FIG. 14 is a diagram illustrating an exemplary configuration of the pixel circuit shown in FIG. 13;

FIGS. 15A, 15B, and 15C are illustrating an exemplary structure of the organic EL panel according to an exemplary mode of disposition of the photodetection element;

FIGS. 16A and 16B are diagrams illustrating an example of a general configuration of the organic EL display apparatus and illustrating I-V characteristics of an EL element; and

FIGS. 17A and 17B are diagrams illustrating burn-in of the organic EL display panel.

### DESCRIPTION OF THE PREFERRED EMBODIMENTS

Hereinafter, a mode for carrying out the invention (referred to as an embodiment) will be described in order of the following items.

1. Configuration of Display Apparatus

2. Configuration of Pixel Circuit

2-1. Pixel Circuit (First Example)

2-2. Pixel Circuit (Second Example)

3. Exemplary Mode of Disposition of Photodetection Element

4. Disposition of Photodetection Element according to Embodiment

4-1. Structure of Pixel Unit Corresponding to Disposition of Photodetection Element According to Embodiment

4-2. Light Incidence Structure (First Example)

4-3. Light Incidence Structure (Second Example)

4-4. Light Incidence Structure (Third Example)

4-5. Light Incidence Structure (Fourth Example)

4-6. Light Incidence Structure (Fifth Example)

5. Thickness Setting of EL Layer

6. B-Light Screening Configuration

6-1. B-Light Screening Configuration (First Example)

6-2. B-Light Screening Configuration (Second Example)

6-3. B-Light Screening Configuration (Third Example)

7. Configuration of Display Apparatus (Modified Example)

### 1. Configuration of Display Apparatus

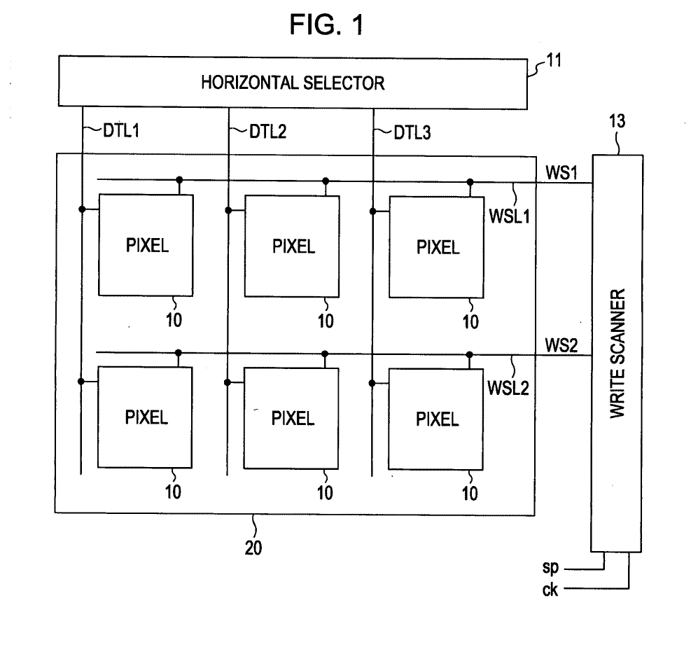

FIG. 1 shows an exemplary configuration of an organic EL display apparatus according to the embodiment.

The organic EL display apparatus is configured to drive each pixel circuit 10 using an organic EL element as a light emitting element to perform light emission driving in an active matrix mode.

As shown in the drawing, the organic EL display apparatus has a pixel array 20 in which a plurality of the pixel circuits 10 is arranged in a matrix of rows and columns (m rows×n columns). In addition, the pixel circuits 10 correspond to several light emitting pixels of R (red), G (green), and B (blue). A color display apparatus is configured so that the pixel circuits 10 of the respective colors are arranged in a predetermined format.

As components for driving each pixel circuit 10 to perform light emission, the display apparatus according to the embodiment includes a horizontal selector 11 and a write scanner 13.

Further, signal lines DTL1, DTL2 . . . , which supply the pixel circuit 10 with a voltage according to a signal value (a grayscale level) of a luminance signal as display data when being selected by the horizontal selector 11, are arranged in the column direction in the pixel array 20. The signal lines DTL1, DTL2 . . . are arranged by the number of columns of the pixel circuits 10 arranged in the matrix in the pixel array 20.

Further, in the pixel array 20, write control lines WSL1, WSL2 . . . are arranged in the row direction. These write control lines WSL are arranged by the number of rows of the pixel circuits 10 arranged in the matrix in the pixel array 20.

The write control lines WSL (WSL1, WSL2 . . . ) are driven by the write scanner 13. The write scanner 13 sequentially supplies scan pulses WS (WS1, WS2 . . . ) to the respective write control lines WSL1, WSL2 . . . arranged in rows at predetermined timings, thereby line-sequentially scanning the pixel circuits 10 on a row-by-row basis.

Furthermore, the write scanner 13 sets the scanning pulses WS on the basis of a clock ck and a start pulse sp.

In accordance with the line-sequential scanning performed by the write scanner 13, the horizontal selector 11 outputs the signal voltages corresponding to the display data (the grayscale level) of the pixel units to the signal lines DTL1, DTL2 . . . arranged in the column direction.

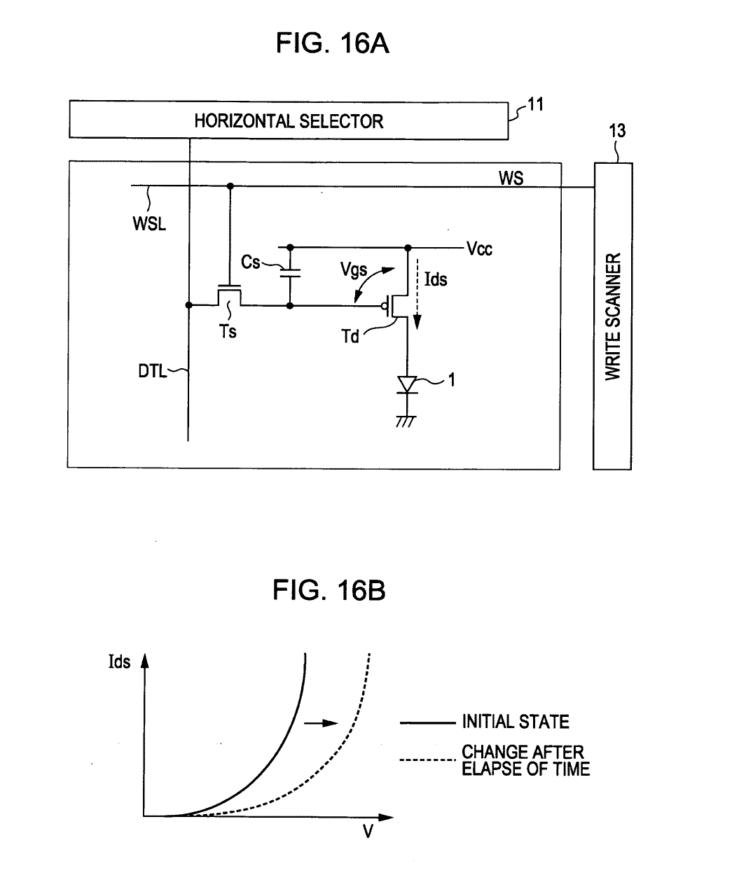

First, for example, a basic configuration of the pixel circuit 10 is shown in FIG. 16A.

That is, in the basic configuration, the pixel circuit 10 includes a sampling transistor Ts formed by an n-channel TFT, a storage capacitor Cs, a driving transistor Td formed by a p-channel TFT, and an organic EL element 1.

For example, in this case, the sampling transistor Ts is the n-channel TFT (Thin Film Transistor), and the driving transistor Td is the p-channel TFT, but all of them may employ the n-channel TFTs. Oxides such as ZnO and IGZO may be employed in the channel material of the transistor.

The gate of the sampling transistor Ts is connected to the write control line WSL extended from the write scanner 13. The drain and the source of the sampling transistor Ts are connected between the signal line DTL and the gate of the driving transistor Td.

The source and the drain of the driving transistor Td are connected between a power supply Vcc and an anode of the organic EL element 1. The cathode of the organic EL element 1 is connected to earth. The organic EL element 1 has a diode structure, and includes the anode and the cathode as described above.

Additionally, the storage capacitor Cs is inserted between the gate of the driving transistor Td and the connection point between the driving transistor Td (the source) and the power supply Vcc.

The light emission of the organic EL element 1 is basically driven as follows.

At the timing when the signal voltage is applied to the signal line DTL, the sampling transistor Ts becomes conductive in response to the scanning pulse WS transmitted from the write scanner 13 through the write control line WSL. Accordingly, the signal voltage from the signal line DTL is written in the storage capacitor Cs, and is held by the storage capacitor Cs.

Since the storage capacitor Cs holds the signal voltage, a voltage between both ends of the storage capacitor Cs, that is, the gate-source voltage Vgs according to the signal voltage is generated in the driving transistor Td. Accordingly, the driving transistor Td passes the current Ids according to the gate-source voltage Vgs to the organic EL element 1. That is, the current Ids according to the signal voltage flows to the organic EL element 1, and thus the organic EL element 1 emits light with a luminance of a grayscale level according to the current Ids.

For example, the pixels are driven so that one horizontal line is sequentially scanned for each frame period, thereby displaying an image. Further, each pixel structure including the pixel circuit 10 is configured to emit any of R, G, and B light in accordance with the position thereof, thereby displaying a color image.

### 2. Configuration of Pixel Circuit

### 2-1. Pixel Circuit (First Example)

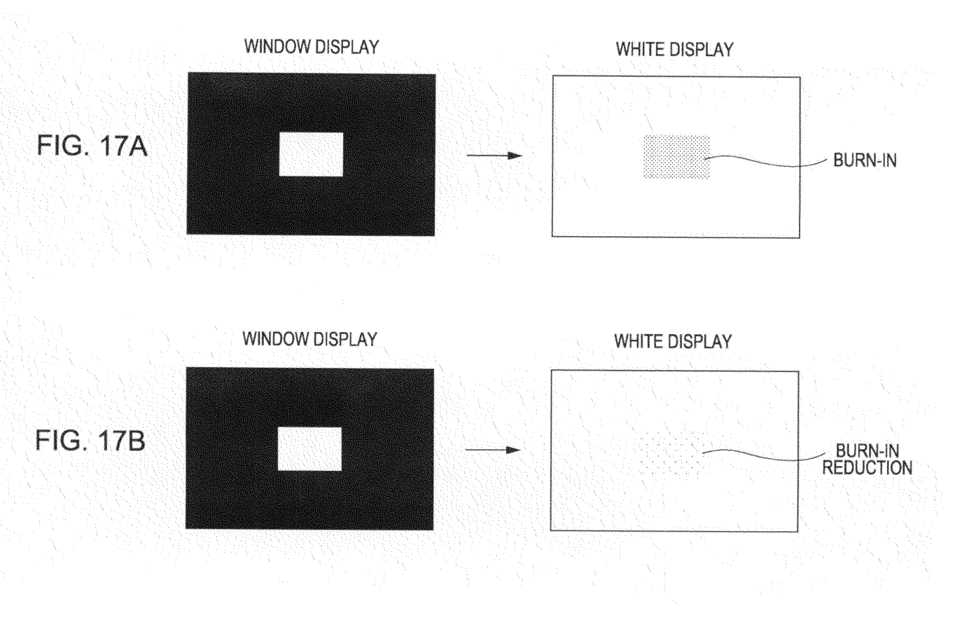

First, as described above with reference to FIG. 16B, the organic EL element 1 is deteriorated so that the luminous efficiency is lowered with time. That is to say, as time passes, the amount of current (Ids) relative to the constant voltage V is reduced, and thus the amount of luminescence is lowered to that extent. This is the cause of the burn-in described in FIG. 17A.

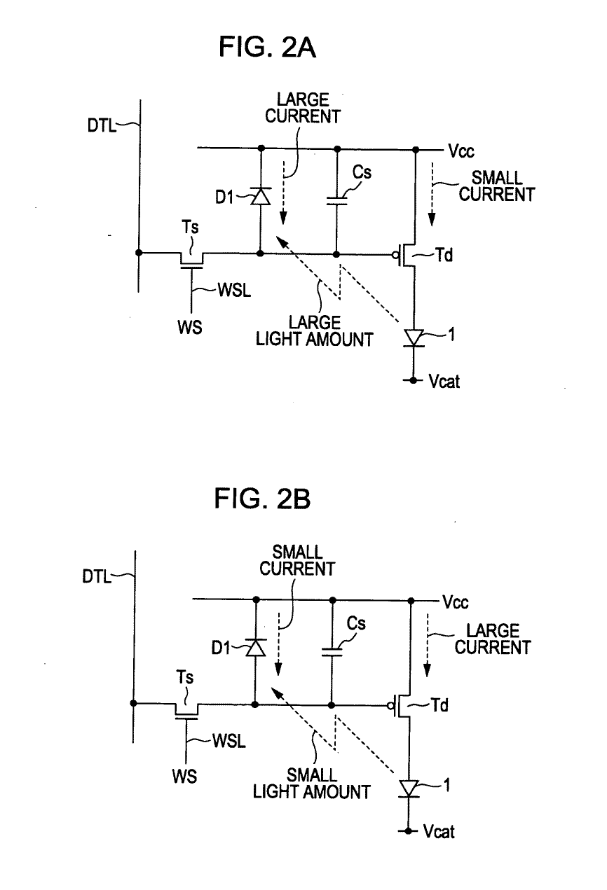

In the embodiment, in order to correct the burn-in, the pixel circuit 10 is configured as shown in FIG. 2. In addition, the configuration of the pixel circuit 10 shown in FIG. 2 is a first example.

The pixel circuit 10 shown in FIG. 2A has the same basic configuration as shown in FIG. 16A, and thus includes the sampling transistor Ts formed by an n-channel TFT, the storage capacitor Cs, the driving transistor Td formed by a p-channel TFT, and the organic EL element 1. It is preferable to use the same materials and the structures of the elements as described in the basic configuration of the pixel circuit 10 mentioned above. Further, the connection mode of the elements is the same as that in the case of the basic configuration of the pixel circuit 10.

However, in the drawing, the cathode of the photodetection element D1 is connected not to the earth potential but to the predetermined cathode potential Vcat.

Moreover, the pixel circuit 10 shown in FIG. 2A includes the photodetection element D1. The photodetection element D1 is formed as a diode or like. For example, the photodetection element D1 is configured so that the anode thereof is connected to the gate of the driving transistor Td and the cathode thereof is connected to the power supply Vcc, and is thus connected in parallel to the storage capacitor Cs.

In this case, the photodetection element D1 generates current when detecting light with a negative bias given, and has a characteristic in which the amount of current increases in accordance with an increase in the detected light amount. The photodetection element D1 is provided to be able to receive and detect the light which is generated from the organic EL element 1.

In addition, generally the photodetection element D1 is formed by using a PIN diode or amorphous silicon, but the embodiment of the invention is not particularly limited to this. For example, other elements may be used if only the elements have a characteristic that changes the amount of flowing current in accordance with the incident light amount.

FIG. 2A shows an operation of the pixel circuit 10, which has the photodetection element D1, according to the embodiment when deterioration of the organic EL element 1 does not progress.

At this time, the light amount, which can be obtained by the light emission of the organic EL element 1, increases accordingly. Then, the photodetection element D1 detects the large light amount, and thus allows a large current to flow accordingly. In such a manner, in response to the flow of current through the path parallel to the storage capacitor Cs, the voltage between both ends of the parallel circuit of the storage capacitor Cs//photodetection element D1, that is, the voltage Vgs between the gate and the source of the driving transistor Td is lowered. Thereby, the current flowing to the organic EL element 1 is controlled to be reduced to the same extent.

Next, FIG. 2B shows an operation of the pixel circuit 10 when deterioration of the organic EL element 1 progresses in accordance with the passage of a certain time period from the time of FIG. 2A for example.

When deterioration of the organic EL element 1 progresses as shown in FIG. 2B, under the same power supply Vcc and the signal voltage conditions as those in FIG. 2A, the luminance of the light emission of the organic EL element 1 decreases.

Hence, the photodetection element D1 detects a light amount smaller than that in the case of FIG. 2A, and thus allows the current to flow by an amount which is smaller than that in the case of FIG. 2A. Then, the degree of the decrease in the voltage Vgs between the gate and the source of the driving transistor Td becomes smaller than that in the case of FIG. 2A. Therefore, the gate-source voltage Vgs is controlled to increase. Thereby, the driving transistor Td passes the current Ids which increases in accordance with the increase in the gate-source voltage Vgs. As a result, the current, which flows to the organic EL element 1, also increases, and thus the luminance of light emission of the organic EL element 1 also increases.

In such a manner, each pixel circuit 10 shown in FIGS. 2A and 2B controls the amount of current, which flows from the driving transistor Td to the organic EL element 1, to increase in accordance of a decrease in luminous efficiency due to the progress of deterioration of the organic EL element 1. Thereby, change in the luminance of light emission due to the deterioration of the organic EL element 1 is suppressed. For example, even when the display is performed during the passage of time as shown in FIG. 17A, if only the pixel circuit 10 of FIG. 2A or 2B is provided, the luminance of the part on which the window shape is displayed is nearly equivalent to the surrounding white part as shown in FIG. 17B. Consequently, burn-in is corrected.

### 2-2. Pixel Circuit (Second Example)

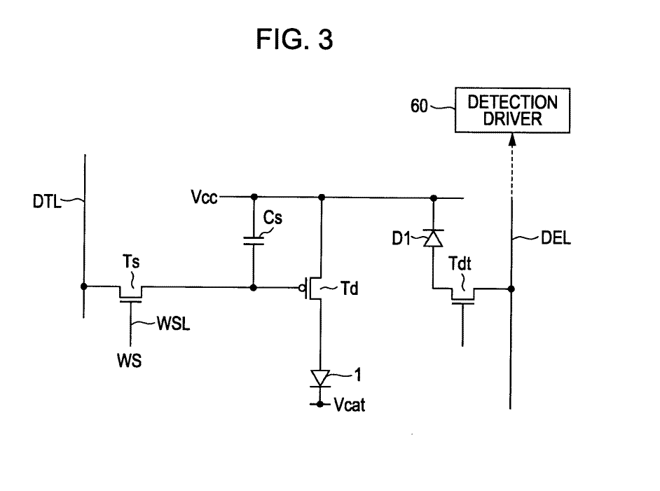

FIG. 3 shows a configuration of a second example as the pixel circuit 10 according to the embodiment. In addition, in the drawing, the components common to those in FIGS. 2A and 2B will be referenced by the same reference numerals and signs, and description thereof will be omitted.

In FIG. 3, the cathode of the photodetection element D1 is connected to the Vcc, and the anode is connected to a detection line DEL through the drain and the source of the transistor Tdt. The detection line DEL is extracted from a detection driver 60.

In the configuration shown in the drawing, for example, the transistor Tdt is driven to be turned on at a set detection timing. In the period during which the transistor Tdt is turned on, the current, which corresponds to the amount of light detected by the photodetection element D1, is input from the detection line DEL to the detection driver 60.

When the input current is detected, the detection driver 60 compares the current value with the signal voltage which is applied from the signal line DTL. Due to the comparison, it is possible to determine an aberration between an ideal current value, which should be obtained in accordance with the signal voltage, and the actually input current value. Accordingly, the detection driver provides the signal voltage value, which is corrected on the basis of the aberration, for the horizontal selector 11. The horizontal selector 11 outputs the signal voltage value. In the configuration of the pixel circuit 10 of the second example, burn-in correction is performed by feedback control of the control system including the detection driver 60 and the horizontal selector 11.

### 3. Exemplary Mode of Disposition of Photodetection Element

Here, in the display panel, a physical part corresponding to one pixel circuit 10 is defined as a pixel unit.

When color image based on three primary colors of R (red), G (green), and B (blue) is displayed by the organic EL display apparatus, a display panel is configured so that R pixel units, G pixel units, and B pixel units are arranged in a predetermined array pattern. Each R pixel unit is a pixel unit which emits red light (R light), and each G pixel unit is a pixel unit which emits green light (G light). In addition, each B pixel unit is a pixel unit which emits blue light (B light).

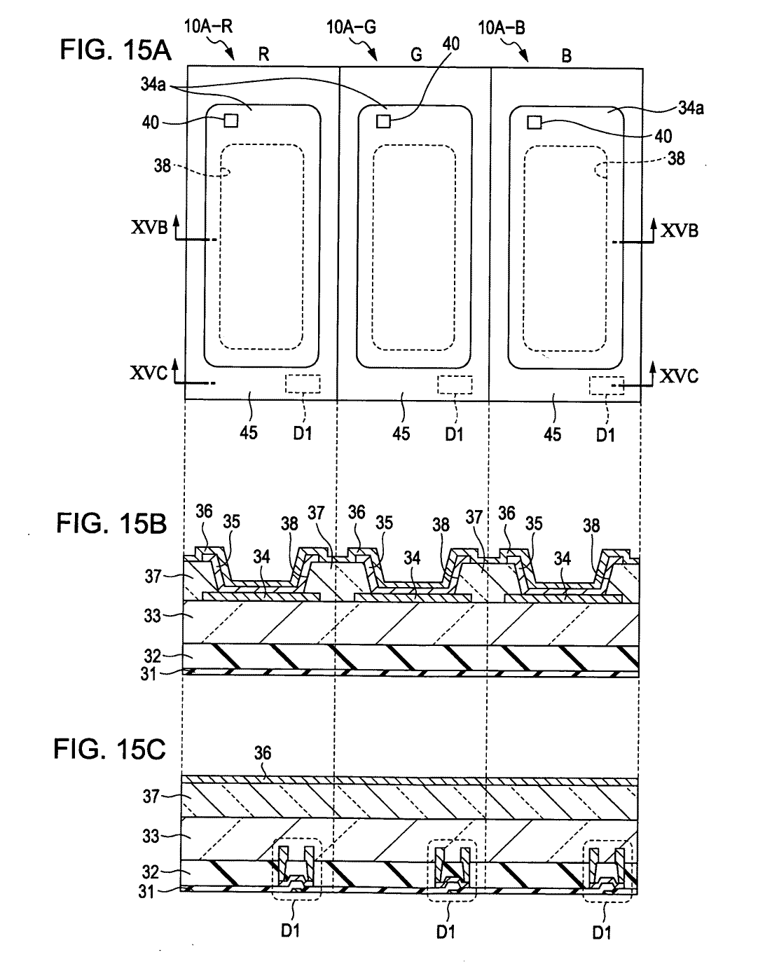

FIGS. 15A to 15C show a considerable example of a structure of the display panel portion formed of one set of an R pixel unit 10A-R, a G pixel unit 10A-G, and a B pixel unit 10A-B corresponding to the disposition of the photodetection elements.

In this example, for example, the R pixel unit 10A-R, the G pixel unit 10A-G, and the B pixel unit 10A-B, which constitutes one set of pixel groups capable of displaying colors, are arranged in the horizontal direction. Further, the structure shown in the drawing corresponds to the top-emission-structure in which light of organic molecules is emitted from the top of the TFT substrate. The top emission structure has an advantage in that the efficiency of light use is increased as compared with, for example, the bottom-emission-structure in which light is emitted from the bottom of the TFT substrate.

FIG. 15A is a top plan view of the one set of R pixel unit 10A-R, G pixel unit 10A-G, and B pixel unit 10A-B. FIG. 15B is a sectional view taken along the line XVB-XVB of FIG. 15A. FIG. 15C is a sectional view taken along the line XVC-XVC of FIG. 15A.

In addition, in the following description, when it is not necessary to particularly distinguish pixel units into the R pixel unit 10A-R, the G pixel unit 10A-G, and the B pixel unit 10A-B, the pixel units may be simply represented as pixel units 10A.

First, the portions corresponding to the R, G, and B pixel units 10A has a layered structure in which a gate insulation layer 31, an interlayer insulation layer 32, and a planarization layer (PLNR) 33 are laminated in order from the bottom of the drawing to the top as shown in FIGS. 15B and 15C. Moreover, as shown in FIG. 15B, each anode metal 34 is formed on the planarization layer 33 for each of the R pixel unit 10A-R, G pixel unit 10A-G, and the B pixel unit 10A-B, and a window layer 37 is additionally formed thereon. For example, with such a configuration, the window layer 37 is formed after the formation of the anode metal 34, and thus the periphery of the anode metal 34 is covered with the window layer 37 formed thereon. Further, in FIG. 15A, the planar portion of the formed anode metal 34 is represented as a planar anode metal portion 34a.

Each anode contact 40 functions as a line connection terminal for connecting the driving transistor Td with the anode (anode metal 34) of the organic EL element 1.

The portions of the window layer 37 corresponding to EL opening portions 38 shown in FIGS. 15A and 15B are cut out, and the anode metals 34 are exposed in the cut-out portions.

Next, an EL layer 35 (a light emitting layer) is formed to cover the exposed portions of the anode metals 34 of EL opening portions 38, and a cathode 36 is further formed on the EL layer 35. The part formed of the anode metal 34, the EL layer 35, and the cathode 36 corresponds to the organic EL element 1.

In addition, the R pixel unit 10A-R, the G pixel unit 10A-G, and the B pixel unit 10A-B based on the above-mentioned structure respectively emit only R light, G light, and B light by using a predetermined method. There are several methods and configurations for selectively emitting R light, G light, and B light. In the embodiment, any one of the above methods may be employed.

Further the light of the respective colors is emitted from the respective EL opening portions 38 of the R pixel unit 10A-R, the G pixel unit 10A-G, and the B pixel unit 10A-B.

Here, in the layered structure shown in FIG. 15B, the gate insulation layer 31, the interlayer insulation layer 32, the planarization layer (PLNR) 33, the window layer 37, and the like have, for example, different materials and functions. However, any one of the layers has insulation property, and thus the layers are regarded as insulation layers. In contrast, the anode metal 34, the cathode 36, and the like are regarded as conductive layers.

Here, regarding the disposition mode of the photodetection elements D1, first FIG. 15A shows the positions of the elements in plan view. The photodetection elements D1 are respectively located on portions corresponding to peripheral portions 45 of the R pixel unit 10A-R, the G pixel unit 10A-G, and the B pixel unit 10A-B.

Each peripheral portion 45 is a portion outside the EL opening portion 38 and planar anode metal portion 34a in each pixel unit 10A. Besides, in this case, each photodetection element D1 is positioned at the lower right of the peripheral portion 45 in the page of the drawing.

Further, FIG. 15C shows the positions of the photodetection elements D1 in the layered structures of the pixel units 10A. In the drawing, the photodetection elements D1 are formed in the quadruple-layer portion including the gate insulation layer 31, the interlayer insulation layer 32, the planarization layer 33, and the cathode 36.

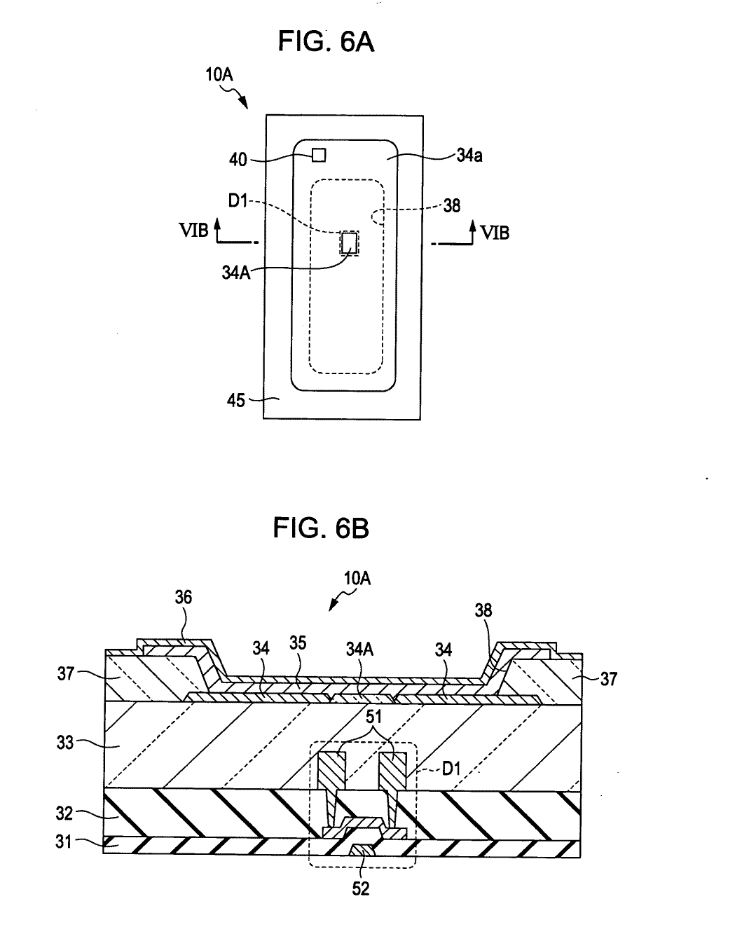

Each photodetection element D1 is represented by a symbol of the diode in FIGS. 2A, 2B, and 3, but in practice, the terminals thereof are physically formed as the gate metal and the source metal as shown in FIGS. 6A and 6B and the like. Any one of the anode and the cathode of the diode as the photodetection element D1 corresponds to the gate metal, and the other one corresponds to the source metal.

In the layered structure, at least the window layer 37, the planarization layer 33, and the cathode 36 have optical transparency. The cathode 36 is made of, for example, a metal such as MgAg, but is very thin, and thus has optical transparency.

Hence, in the photodetection element D1 disposed as described above, leaked light, which is emitted from the EL opening portion 38 and is turned around on the lower layer side, is received by the cathode 36 and the window layer 37 through the planarization layer 33.

The configuration of the pixel driving circuit shown in FIGS. 2A and 2B or FIG. 3 may be applied to the structure shown in the FIG. 15. In this case, ideally, the photodetection element D1 provided in the R pixel unit 10A-R has to receive only the light emitted from the EL opening portion 38 of the same R pixel unit 10A-R. Likewise, the photodetection element D1 provided in the G pixel unit 10A-G has to receive only the light emitted from the EL opening portion 38 of the same G pixel unit 10A-G, and the photodetection element D1 provided in the B pixel unit 10A-B has to receive only the light emitted from the EL opening portion 38 of the same B pixel unit 10A-B. The reason is as follows: for example, when the photodetection element D1 in a certain pixel unit 10A receives the incident light emitted from other pixel units 10A, the current value is changed in accordance with the light reception, and thus it is difficult to obtain an appropriately corrected luminance.

However, for example, as shown in FIGS. 15A to 15C, the photodetection elements D1 may be disposed on the positions corresponding to the peripheral portions 45. In this condition, a substantial amount of light is incident on each photodetection element D1 not only from the pixel unit 10A having itself provided therein but also from other pixel units 10A disposed in the vicinity thereof. This means that each photodetection element D1 receives and detects not only light of a color which is the original detection target but also components of light of other colors. Thus, this makes it difficult to obtain an appropriate burn-in correction effect.

### 4. Disposition of Photodetection Element According to Embodiment

### 4-1. Structure of Pixel Unit Corresponding to Disposition of Photodetection Element According to Embodiment

According to the embodiment, each photodetection element D1 is prevented from receiving the light of a color which is not the detection target thereof as reliably as possible so as to dominantly receive the light of the color which is the detection target thereof, thereby obtaining a more optimized result in the burn-in correction. Hereinafter, the configuration therefor will be described.

Here, first, in the example of disposition of the photodetection elements shown in FIGS. 15A to 15C, each photodetection element D1 is disposed, in plan view, on the position corresponding to the peripheral portion 45 outside the EL opening portion 38.

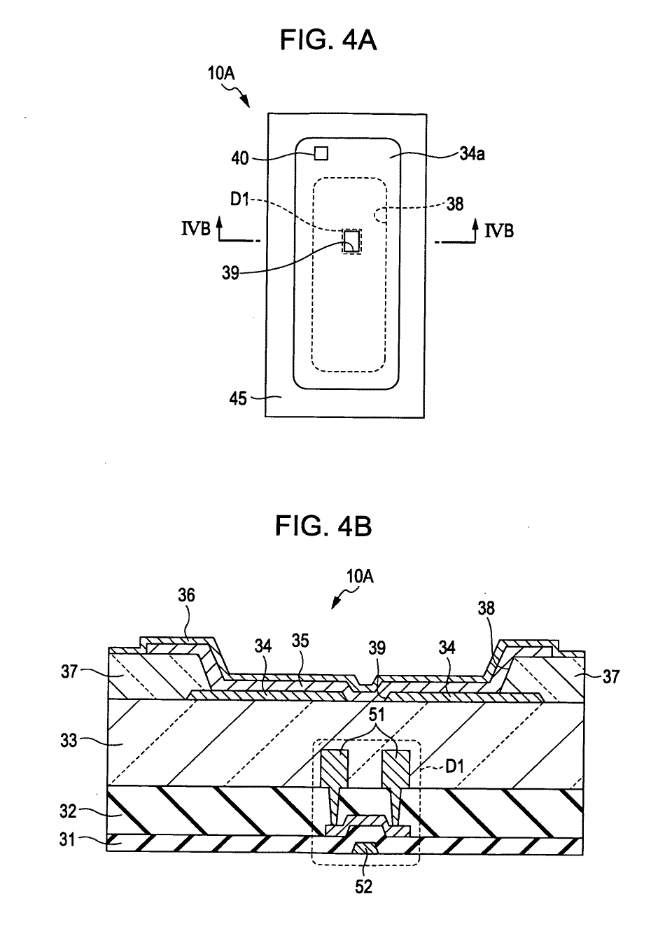

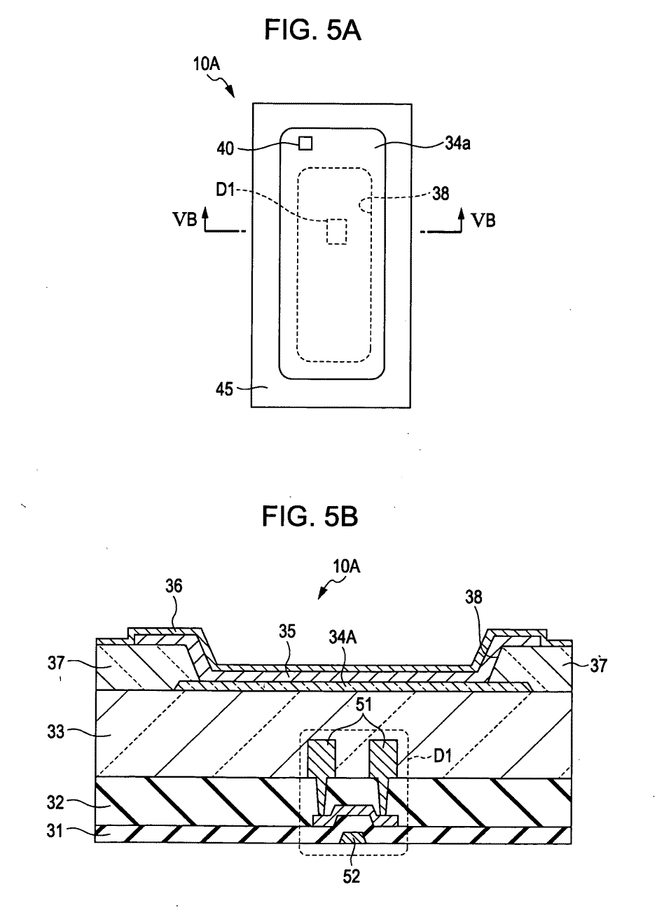

In contrast, in the disposition of the photodetection element according to the embodiment, the photodetection element D1 is disposed as shown in FIGS. 4A and 4B. In addition, FIGS. 4A and 4B show one selected pixel unit 10A. The pixel unit 10A shown in the drawings corresponds to any of the R pixel unit 10A-R, the G pixel unit 10A-G, and the B pixel unit 10A-B shown in FIGS. 15A to 15C. Further, the components common to those in FIGS. 15A to 15C will be referenced by the same reference numerals and signs, and description thereof will be omitted. This is the same in cases of light incidence structures according to second to fifth examples to be described later in FIGS. 5A to 8.

According to the embodiment, as shown in the top plan view of FIG. 4A, the photodetection element D1 is disposed within the EL opening portion 38 in plan view. FIG. 4A shows a mode in which the photodetection element D1 is disposed at substantially the center of the EL opening portion 38 having a substantially rectangular shape.

Further, the position of the disposed photodetection element D1 in the thickness direction of the organic EL panel is shown in the sectional view taken along the line IVB-IVB of FIG. 4A. That is, similarly to the first example of the disposition of the photodetection element shown in FIGS. 15A to 15C, the photodetection elements D1 are formed in the triple-layer portion including the gate insulation layer 31, the interlayer insulation layer 32, and the planarization layer 33.

By disposing the photodetection elements D1 on the position, the photodetection element D1 is positioned, in plan view, within an area which is occupied by the EL layer 35. Consequently, the photodetection element D1 is set to the position capable of receiving the light, which radiates from the EL layer 35, from just upper side thereof.

However, in the disposition, in order for the photodetection element D1 to effectively receive the light which radiates from the EL layer 35, it is necessary to form at least a portion corresponding the EL opening portion 38 as a structure in which the light generated in the EL layer 35 is incident not only to the upper side but also to the lower side layer. The light incidence structure will be described later with reference to the first to fifth examples.

By adopting the structure in which the light generated in the EL layer 35 is incident to the lower side layer, the light generated in the EL layer 35 of the same pixel unit 10A is directly incident, at a very short distance, to the photodetection element D1. At this time, the photodetection element D1 is able to receive the light, which is generated in the EL layer 35, with a very strong intensity. In other words, the photodetection element D1 is able to dominantly receive the light of a color which should be primarily received by itself.

As described above, in the section of disposition of Photodetection element according to Embodiment, considering the disposition of the photodetection element D1, the photodetection element D1 is enabled to more effectively receive the light of a color which should be originally received by itself.

### 4-2. Light Incidence Structure (First Example)

Next, the first to fifth examples of the structure (the light incidence structure) for causing the light, which is generated in the EL layer 35, to be incident to the lower layer side will be described. First, the first example of the light incidence structure will be described.

FIGS. 4A and 4B, which show the disposition of the photodetection element, also show the first example of the light incidence structure.

In the case of the light incidence structure of the first example shown in the drawings, it is the premise that the anode metal 34 is formed by a material which does not have optical transparency. Moreover, as shown in the sectional view taken along the line IVB-IVB of FIG. 4B, a hole portion is formed on a portion of the anode metal 34, thereby providing an anode metal opening portion 39.

The anode metal opening portion 39 is formed, in plan view, for example at substantially the same position as the photodetection element D1 as shown in the top plan view of FIG. 4A.

With such a structure, the light generated in the EL layer 35 is enabled to radiate from the anode metal opening portion 39 to the lower layer side thereof. In addition, the light, which radiates to the lower layer side, is enabled to be more directly incident to the photodetection element D1 formed just below the anode metal opening portion 39.

In addition, in the drawings, the anode metal opening portion 39 is slightly smaller in size than the photodetection element 1 in plan view, and has a rectangular shape, but this is just an example in all respects. The size of the anode metal opening portion 39 may be larger than, for example, that of the photodetection element D1. In addition, the shape thereof is also not limited to a square shape such as a rectangular shape. For example, the shape thereof may be a circular shape or an elliptical shape.

### 4-3. Light Incidence Structure (Second Example)

FIGS. 5A and 5B show a second example of the light incidence structure.

According to the second example of the light incidence structure, as shown in the sectional view taken along the line VB-VB of FIG. 5A, instead of the anode metal 34 which does not transmit light, a transparent anode metal 34A made of a material that transmits light is provided. In addition, in this case, the transparent anode metal 34A has no opening portion formed thereon, but is formed as a solid pattern. As described above, since the transparent anode metal 34A is formed as a solid pattern, it is possible to simplify, for example, a process therefor.

In the structure, the light generated in the EL layer 35 is transmitted through the transparent anode metal 34A, and also radiates to the lower layers. As a result, the light is also effectively incident on the photodetection element D1.

### 4-4. Light Incidence Structure (Third Example)

FIGS. 6A and 6B show a third example of the light incidence structure.

According to the third example of the light incidence structure, as shown in the top plan view of FIG. 6A and the sectional view taken along the line VIB-VIB of FIG. 6A, the anode metal is formed as the transparent anode metal 34A in the portion thereof corresponding to the anode metal opening portion 39 of FIGS. 4A and 4B, and the remaining peripheral portion is formed as the anode metal 34 which does not transmit light.

In this case, also the light generated in the EL layer 35 is transmitted through the transparent anode metal 34A, radiates to the lower layers, and is incident on the photodetection element D1. It may be said that, similarly to the first example, in this case, the portion, which transmits light to the lower layer side, is an area of limited size smaller than that of the anode metal 34, and thus there is an advantage in that, for example, external light is less likely to have an effect thereon.

In addition, in this case, the planar shape and size of the area corresponding to the transparent anode metal 34A is also not particularly limited.

### 4-5. Light Incidence Structure (Fourth Example)

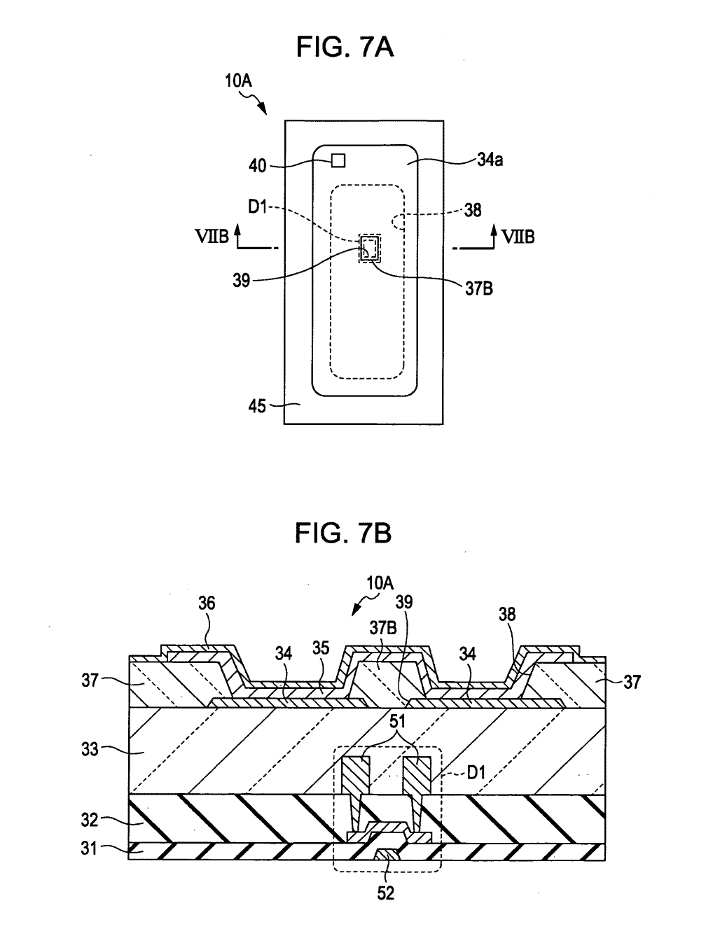

A fourth example of the light incidence structure is shown in the top plan view of FIG. 7A and the sectional view taken along the line VIIB-VIIB of FIG. 7A. In this example, first, the anode metal opening portion 39 is formed similarly to the first example of FIGS. 4A and 4B. Herewith, a transparent window layer 37B is provided above the position corresponding to the anode metal opening portion 39 in the planar direction. In this case, the EL layer 35 and the cathode 36 are formed above the transparent window layer 37B.

In the structure, the light generated in the EL layer 35 radiates from the transparent window layer 37B to the layers located below the planarization layer 33 (or a B-light blocking planarization layer 33A) through the anode metal opening portion 39, and is incident on the photodetection element D1.

In addition, in this case, the shape and size of the transparent window layer 37B is also not particularly limited.

Further, a modified example of the fourth example of the light incidence structure may be based on, for example, the second example of the light incidence structure. In this case, it can be considered that the anode metal is formed as a solid and transparent anode metal 34A. Further, similarly to the third example of the light incidence structure shown in FIGS. 6A and 6B, this structure may be combined with the structure in which the transparent anode metal 34A is formed in the opening portion of the anode metal 34.

In addition, in a case where the second example or the third example is employed as a B-light blocking configuration to be described later, the window layer 37 and the transparent window layer 37B shown in the drawings are made of a material of a B-light blocking window layer 37A.

### 4-6. Light Incidence Structure (Fifth Example)

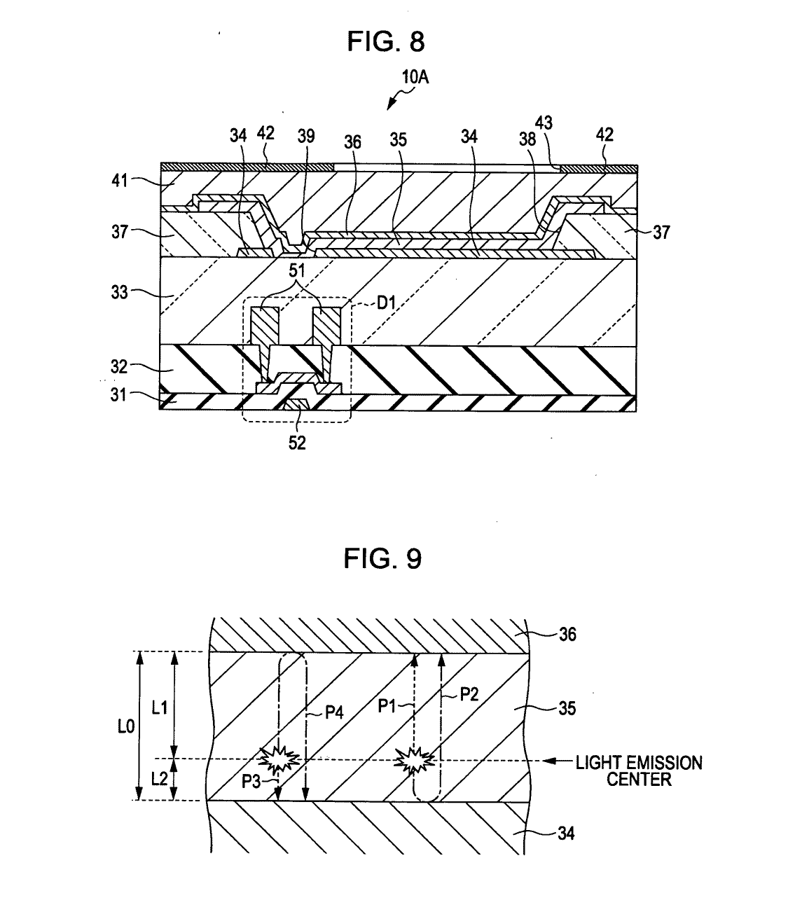

In a light incidence structure of a fifth example, as shown in the sectional view of FIG. 8, a panel structure provided with a black matrix 42 is premised. In addition the sectional view in the drawing also shows a section taken along IVB-IVB, VB-VB, VIB-VIB, and VIIB-VIIB, which are, for example, at the same position as FIGS. 4A, 5A, 6A, and 7A.

The black matrix 42 is formed throughout the entire array surface of the pixel units 10A, and is formed in, for example, a black pattern in which a portion thereof corresponding to the EL opening portion 38 (the opening portion of the light emitting element) is cut out. Further, the black matrix 42 is formed as a layer located above the organic EL element 1. The cut-out portion of the black matrix 42 corresponding to the EL opening portion 38 is a black matrix opening portion 43. In this case, a transparent protective layer 41 is formed on the cathode 36, and the black matrix 42 is formed on the surface of the protective layer 41.

By providing the black matrix 42, portions, which do not transmit light of the color black, are formed on the boundary portions of the respective color pixel units 10A. Thereby, for example, the contrast of the displayed image is improved.

Moreover, according to the fifth example of the light incidence structure, as shown in the drawing, the anode metal opening portion 39 is provided below the black matrix 42. Further, also the photodetection element D1 is provided to be positioned, in the planar direction, just below the anode metal opening portion 39 at the position below the same black matrix 42.

With such a configuration, by providing the anode metal opening portion 39 below the black matrix 42, it is possible to reduce the effects of the external light incident on the photodetection element D1, for example, from the black matrix opening portion 43.

In addition, the fifth example can be combined with any of the first to fourth examples of the light incidence structure described in FIGS. 4A to 7B.

### 5. Thickness Setting of EL Layer

Further, in the case of adopting the configuration of the disposition of the photodetection element of the embodiment, according to the embodiment, the thickness of the EL layer 35 is set in the following manner.

In addition, the thickness setting of the EL layer 35 in the embodiment can be applied to any of the first example and the third to fifth examples of the above-mentioned light incidence structure. Further, the setting can be effectively applied to first to third examples of the B-light blocking configuration to be described later.

First, the organic EL element 1 of the embodiment has a cavity structure as shown in the structure diagrams (the sectional views) of FIG. 9, FIGS. 4A to 8 described hitherto, and the like. That is, the cathode 36 above the EL layer 35 (the light emitting layer) is formed as a semi-transmissive film (a semi-reflective film), and the anode metal 34 below the EL layer 35 is formed as a reflective film. Thereby, the light generated in the EL layer 35 repeatedly reflects and interferes with each other between the electrodes of the cathode 36 and the anode metal 34, and radiates through the cathode 36.

The light emission center in FIG. 9 is defined as, for example, a position at which the intensity of emission is highest in EL layer 35 in the height direction of the section thereof. Then, the light, which is generated at the light emission center and radiates upward, takes two paths. That is, as shown in the right side of the drawing, first, in the path P1, the light directly radiates upward. In the path P2, the light travels downward first, is reflected by the anode metal 34, and then radiates upward.

In this case, relative to the distance L0, which corresponds to the thickness of the entire EL layer 35, from the lower side surface of the cathode 36 to the surface of the anode metal 34, the distance of the EL layer 35 from the light emission center to the lower side surface of the cathode 36 is represented by L1, and the distance from the light emission center to the surface of the anode metal 34 is represented by L2 (L0=L1+L2). Further, the peak wavelength of the spectrum of the colored light which should radiate from the EL layer 35 is represented by λ. In addition, the distances L1 and L2 are set to the integer multiples of λ. That is, any of the optical paths P1 and P2 is set to have a distance equal to the integer multiple of λ. The optical path P1 has a length equal to the distance L1, and the length of the optical path P2 is represented by L1+2*L2. As described above, when the direct optical path P1 and the reflective optical path P2 are respectively set to have optical path lengths equal to the integer multiples of λ, due to the interference effect caused by reflection, the spectrum of the light, which is extracted through the cathode 36, becomes steep. Thus, for example, in a color display, it is possible to obtain effects of improvement in chromatic purity and the like.

In addition, as described above, when the distances L1 and L2 are set to the integer multiple of λ, even from the light which is extracted on the lower layer side, steep spectrum can be obtained.

That is, the direct optical path P3 shown on the right side of FIG. 9 has a distance from the light emission center to the surface of the anode metal 34. However, this is equal to the distance L2, and thus the length of the optical path P3 is equal to the integer multiple of λ. Further, a reflective optical path P4 shown on the left side of FIG. 9 is represented by 2*L1+L2, and thus has an optical path length equal to the integer multiple of λ. Then, for example, although not shown in the drawing, even the light, which repeatedly reflects between the cathode 36 and the anode metal 34 and exits from the anode metal opening portion 39, has steep spectrum. Here, the spectrum of the radiated light becomes steep, which means that the radiated light can be enhanced. That is, as described above, in accordance with the setting of the thickness (L1, L2) of the EL layer 35, it is possible to enhance not only the light, which radiates to the upper layer side, but also the light which is incident on the photodetection element D1 on the lower layer side. In the embodiment, with such a configuration of the EL layer 35, the light generated in the same pixel unit 10A is also made to be more effectively incident on the photodetection element D1 on the lower layer side of the EL layer 35.

### 6. B-Light Screening Configuration

### 6-1. B-Light Screening Configuration (First Example)

Incidentally, among the R light which radiates from the R pixel unit 10A-R, the G light which radiates from G pixel unit 10A-G, and the B light which radiates from the B pixel unit 10A-B, the light with the shortest wavelength is the B light. Hence, the energy of the B light is stronger than the R light and the G light. For example, in practice, depending on the photodetection element D1, high sensitivity is set to be able to effectively detect even the light which is weak to a certain extent. In accordance with the luminance setting, actually, the energy of the B light with a short wavelength relative to the R light and the G light is set to be extremely strong. Hence, regarding the crosstalk of the light incident on the photodetection element D1, particularly in practice, a problem arises in that the B light is incident on the pixel units 10A corresponding to different colors (R and G). Conversely, when the incident light amount of the B light incident on the photodetection elements D1 of the R pixel unit 10A-R and the G pixel unit 10A-G is effectively suppressed, it is possible to very satisfactorily correct the burn-in.

For this reason, in the embodiment, the organic EL display apparatus further has the B-light blocking configuration to be described later, in addition to the configurations described in FIGS. 4A to 9.

As the B-light blocking configurations, first to third examples are given.

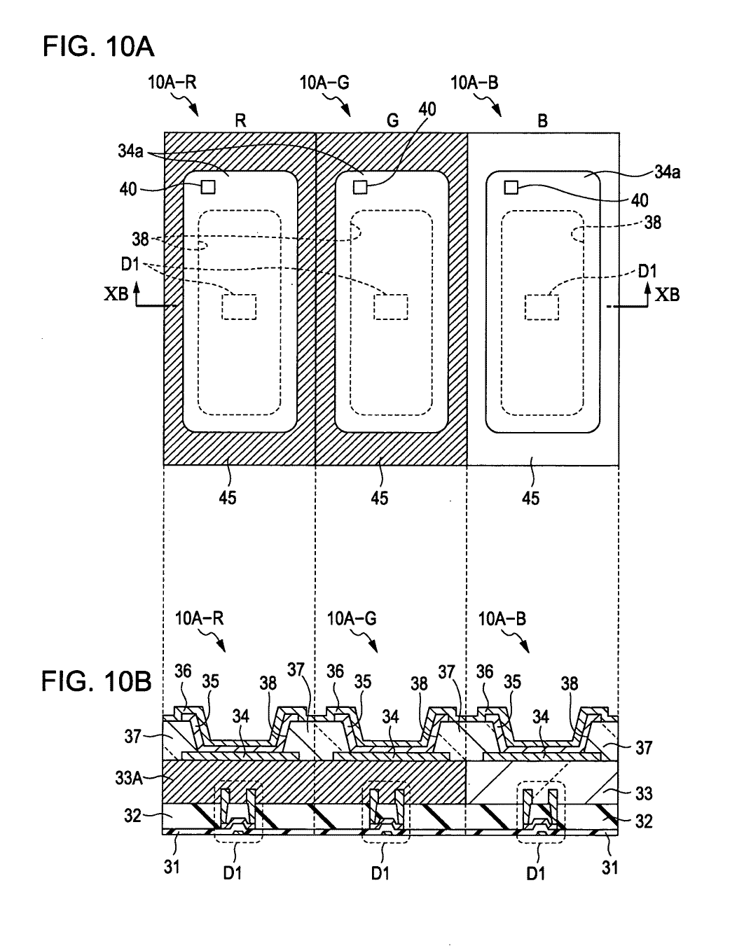

FIGS. 10A and 10B show the B-light blocking structure of the first example.

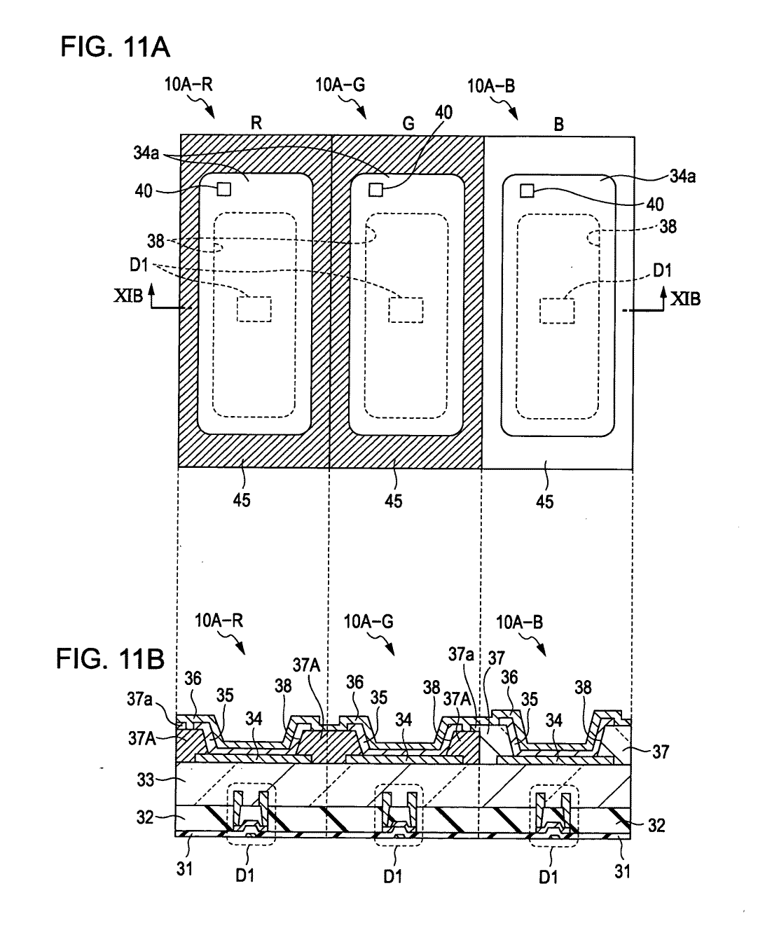

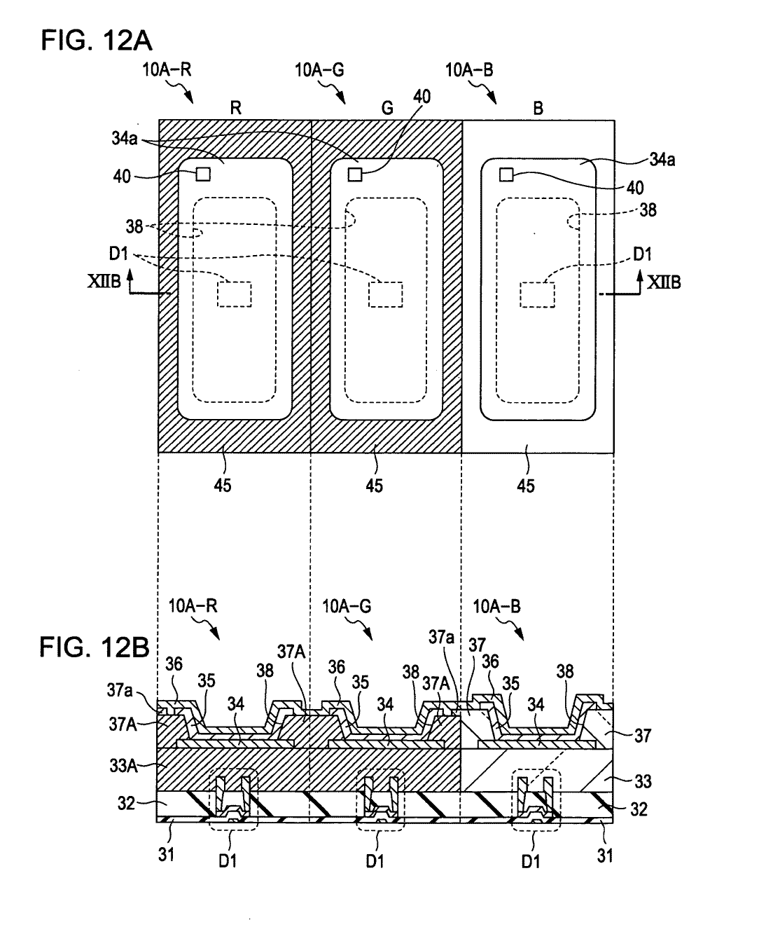

In addition, in FIGS. 10A and 10B, the structure and disposition of the respective portions is the same as those of FIGS. 15A to 15C. Therefore, the components common to those in FIGS. 15A to 15C will be referenced by the same reference numerals and signs, and description thereof will be omitted. Further, in the drawings, the anode metal 34 is formed without the opening portion. Thus, the light incidence structure in the drawing corresponds to that of the second example, but the B-light blocking structure described herein can be applied to the examples of other light incidence structures. From this point of view, it is the same in FIGS. 11A to 12B corresponding to the B-light blocking configurations of the second and third examples to be describe later.

According to the first example, as shown in FIG. 10E, as the planarization layer in the R pixel unit 10A-R and the G pixel unit 10A-G, the B-light blocking planarization layer 33A is employed. The B-light blocking planarization layer 33A has a characteristic that blocks the B light and transmits the R light and the G light by selection of wavelength. In addition, “blocking” described herein means that the transmittance of the B light is low to the extent that the photodetection element D1 effectively does not receive the B light. That is, the B-light blocking planarization layer 33A is a layer having a characteristic in which the transmittance of the B light is lower than the transmittance of the R light and the G light.

Further, the remaining B pixel unit 10A-B employs the planarization layer 33 (of which the transmittance of the B light is higher than that of the B-light blocking planarization layer 33A) that transmits at least the B light.

The material of the B-light blocking planarization layer 33A, which blocks the B light as described above, may employ, for example, novolac. In the structure shown in FIGS. 10A and 10B, the R pixel unit 10A-R and the G pixel unit 10A-G are made to be adjacent to each other. Therefore, the B-light blocking planarization layer 33A can be commonly formed over the range of the R pixel unit 10A-R and the G pixel unit 10A-G.

Further, the material of the planarization layer 33, which transmits the B light, may employ polyimide.

The photodetection element D1 is formed in the laminated portion including the planarization layer and the layers on the lower side thereof. It can be seen that the planarization layer resides in the path in which the light radiating from the EL opening portion 38 is incident on the lower layer side so as to be turned around and reaches the photodetection element D1.

Accordingly, by providing the B-light blocking planarization layer 33A in such a manner, the B light, which is incident on the photodetection elements D1 of the R pixel unit 10A-R and the G pixel unit 10A-G, is blocked, or the incident light amount is made to be extremely small.

As a result, the R light and the G light are respectively dominant in the light which is received in the photodetection elements D1 of the R pixel unit 10A-R and the G pixel unit 10A-G. Thereby, in each of the R pixel unit 10A-R and the G pixel unit 10A-G, it is possible to perform an operation of burn-in correction appropriate for the deterioration state of the EL layer 35. Further, in the B pixel unit 10A-B, by providing the planarization layer 33 which transmits the B light, the B light is dominantly incident on the photodetection element D1. Therefore, it is possible to perform an operation of burn-in correction appropriate for the deterioration state of the EL layer 35.

### 6-2. B-Light Screening Configuration (Second Example)

FIGS. 11A and 11B show the second example of the B-light blocking configuration.

In the case of the drawings, the window layer 37A of the R pixel unit 10A-R and the G pixel unit 10A-G employs a material which blocks the B light and transmits the R light and the G light by selection of wavelength. Further, in the B pixel unit 10A-B, the window layer 37, which transmits the B light, is provided.

With such a configuration, the B light, which is incident on the photodetection elements D1 of the R pixel unit 10A-R and the G pixel unit 10A-G, is reduced in intensity, and the incidence of the R light and the G light is dominant. In addition, in the B pixel unit 10A-B, the incidence of the B light is dominant. Thereby, in the pixel units 10A of the respective colors, it is possible to perform an operation of burn-in correction appropriate for the deterioration state of the EL layer 35.

In addition, in the structure shown in FIGS. 11A and 11B, also the R pixel unit 10A-R and the G pixel unit 10A-G are made to be adjacent to each other. Therefore, the B-light blocking window layer 37A can be commonly formed over the range of the R pixel unit 10A-R and the G pixel unit 10A-G.

Moreover, in this case, since the B-light blocking window layer 37A corresponding to the R pixel unit 10A-R and the G pixel unit 10A-G and the window layer 37 corresponding to the B pixel unit 10A-B have different materials, the processes of those are also different.

Consequently, in this case, as show in FIG. 11B, first the B-light blocking window layer 37A is formed, and then the window layer 37 is formed. In such a manner, in the window layer 37, an overlap portion 37a, which is a portion covering the upper side of the B-light blocking window layer 37A, is formed.

In the portion on which the overlap portion 37a is formed as described above, the distance from the anode metal 34 to the window layer surface is set to be longer than before. Thereby, at the time of vapor deposition for forming layers as the organic EL element 1, it is possible to reduce a probability, a possibility that the deposition mask, the transfer substrate, and the like come into contact with the anode metal 34 exposed in the EL opening portion 38. When the deposition mask or the transfer substrate comes into contact with the anode metal 34, this causes pointlike defects based on dark points. That is, by forming the overlap portion 37a, the probability of causing a pointlike defect is reduced. Thereby, it is possible to improve the yield ratio of the organic EL panel, and it is also possible to obtain high-quality organic EL panels having fewer pointlike defects.

In the case of FIGS. 11A and 11B, the overlap portion 37a is formed in the window layer 37 of the B pixel unit 10A-B. Therefore, the above-mentioned effect can be remarkably obtained in the B pixel unit 10A-B. However, regarding the R pixel unit 10A-R and the G pixel unit 10A-G, as shown in FIG. 11B, the portion, in which these two pixel units are arranged in series, may be regarded as one pixel unit. In this case, it can be regarded that the overlap portions 37a are at both edges thereof. Accordingly, in the R pixel unit 10A-R and the G pixel unit 10A-G, it is also possible to sufficiently reduce the probability that the deposition mask and the transfer substrate come into contact with the anode metal 34.

In addition, after the window layer 37 of the B pixel unit 10A-B is formed, the B-light blocking window layer 37A of the R pixel unit 10A-R and the G pixel unit 10A-G may be formed, and thus the overlap portion may be formed on the B-light blocking window layer 37A side. In this case, it is also possible to obtain the same effect as described above.

### 6-3. B-Light Screening Configuration (Third Example)

FIGS. 12A and 12B show the third example of the B-light blocking configuration.

In the third example shown in the drawings, the configurations of the first example and the second example shown in FIGS. 10A to 11B are combined.

That is, in the R pixel unit 10A-R and the G pixel unit 10A-G, the B-light blocking planarization layer 33A and the B-light blocking window layer 37A are formed. In the B pixel unit 10-B, the planarization layer 33 and the window layer 37, which transmit at least the B light, are formed.

Thus, by employing the B-light blocking planarization layer 33A and the B-light blocking window layer 37A as two layers in the organic EL panel, it is possible to reduce the intensity of the B light which is incident on the R pixel unit 10A-R and the G pixel unit 10A-G. As a result, a more appropriate operation of burn-in correction can be expected.

Further, as can be seen from FIG. 12B, in the third example, similarly to the second example, the overlap portion 37a is formed in the window layer 37, thereby achieving reduction in dark points.

### 7. Configuration of Display Apparatus (Modified Example)

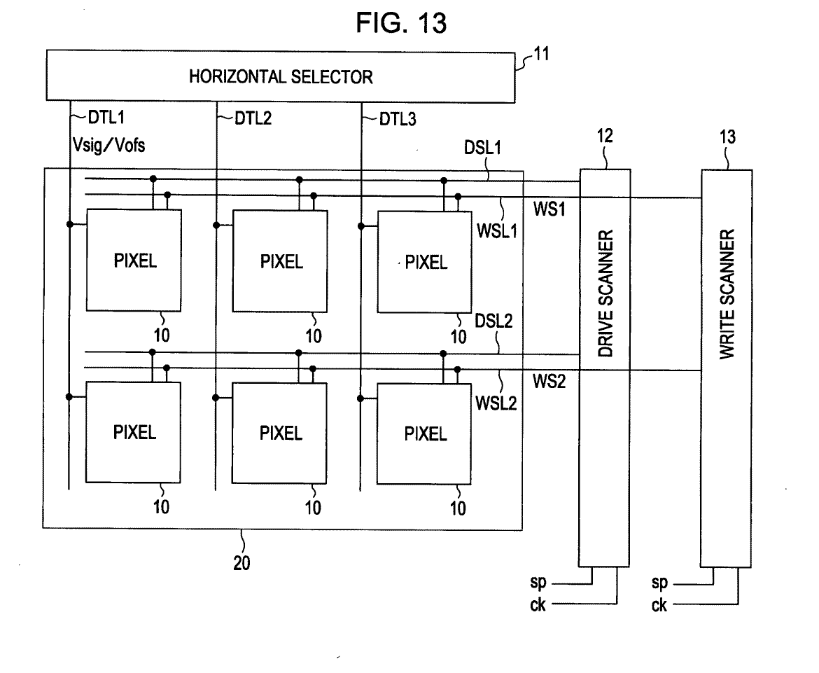

FIG. 13 shows another exemplary configuration of an organic EL display apparatus according to a modified example of the embodiment. In addition, in this drawing, the components common to those in FIG. 1 will be referenced by the same reference numerals and signs, and description thereof will be omitted.

The organic EL display apparatus shown in FIG. 13 is further provided with a drive scanner 12.

The drive scanner 12 is connected with power supply control lines DSL (DSL1, DSL2 . . . ). Each power supply control line DSL (DSL1, DSL2 . . . ) is commonly connected, in the same manner as each write control line WSL (WSL1, WSL2 . . . ), to the pixel circuits 10, which form one horizontal line, on a row-by-row basis.

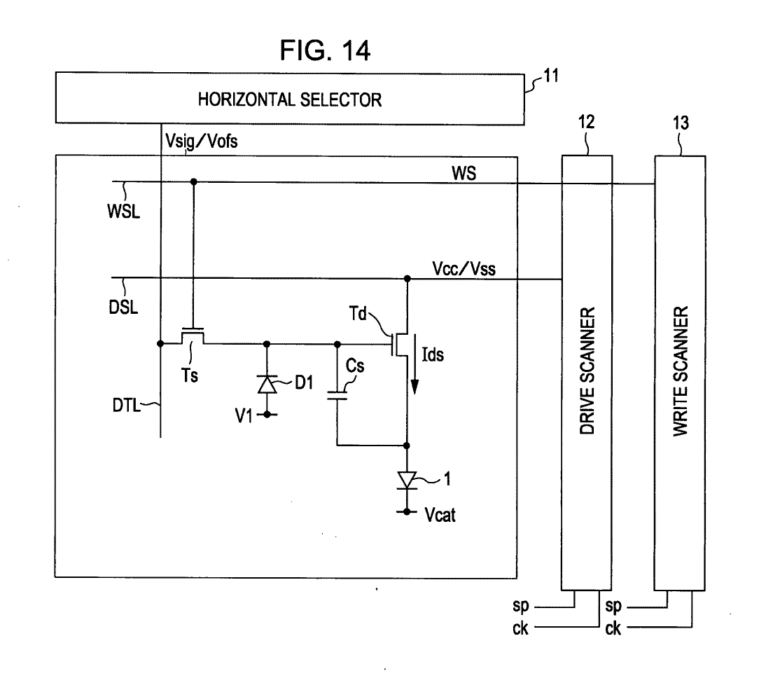

FIG. 14 shows an exemplary configuration of the pixel circuit 10 of FIG. 13 mentioned above. In addition, the drawing shows the horizontal selector 11, the drive scanner 12, and the write scanner 13 together. Further, the components common to those of the pixel circuit 10 shown in FIG. 2 will be referenced by the same reference numerals and signs, and description thereof will be omitted.

The components of the pixel circuit 10 shown in FIG. 14 and the connection mode of the components are the same as FIG. 2. However, in FIG. 14, the power supply control line DSL, which is driven by the drive scanner 12, is connected as the power supply of the driving transistor Td.

The drive scanner 12 alternately applies, on the basis of the clock ck and the start pulse sp, the driving voltage Vcc and the initial voltage Vss to the power supply control line DSL at appropriate timings.

For example, first the drive scanner 12 applies the initial voltage Vss to the power supply control line DSL, and initializes the source potential of the driving transistor Td. Next, in the period during which the horizontal selector 11 supplies the reference value voltage (Vofs) to the signal line DTL, the write scanner 13 makes the sampling transistor Ts conductive, and the gate potential of the driving transistor Td is fixed at the reference value. In this state, the drive scanner 12 applies the driving voltage Vcc, thereby allowing the threshold voltage Vth of the driving transistor Td to be held by the storage capacitor Cs. This is an operation of correcting the threshold voltage of the driving transistor Td.

Thereafter, in the period during which the horizontal selector 11 applies the signal voltage (Vsig) to the signal line DTL, the sampling transistor Ts becomes conductive by control of the write scanner 13, thereby writing the signal value in the storage capacitor Cs. At this time, mobility of the driving transistor Td is also corrected.

Subsequently, the current according to the signal value written in the storage capacitor Cs flows to the organic EL element 1, thereby emitting light at the luminance according to the signal value.

This operation cancels the effects of variation of the characteristics of the driving transistor Td such as the threshold value and the mobility of the driving transistor Td. Further, the voltage between the gate and the source of the driving transistor Td is maintained at a constant value. Therefore, the current flowing to the organic EL element 1 does not fluctuate.

In addition, in the description given hitherto, each photodetection element D1 is provided in each pixel circuit 10 forming the pixel array 20.

However, in most cases, practically the deterioration of the organic EL element corresponding to burn-in is distributed over a wide pixel area which is equivalently deteriorated. On the basis of this, it can be considered that the photodetection element is laid out so that one photodetection element D1 is provided to correspond to the area portion of the size of the predetermined number of horizontal pixel units×the predetermined number of vertical pixel units. In this case, it is appropriate to adopt, for example, the configuration of the pixel circuit according to the second example shown in FIG. 3.

In the case of the configuration, the detection driver 60 sets, in response to the light amount (the current level) detected in the photodetection element D1, the correction signal voltage of the pixel circuit forming the area portion corresponding to the photodetection element D1.

In addition, the configuration can be applied to, for example, the separate colors of R, G, and B. That is, one photodetection element D1 for each of the R light, the G light, and the B light is provided for each area portion of the size of the predetermined number of horizontal pixel units×the predetermined number of vertical pixel units. In such a case, by applying the B-light blocking structure of the embodiment to the pixel units provided with the photodetection elements D1 corresponding to the R light and the G light, it is possible to obtain the same effect as described hitherto.

Further, in the description given hitherto, the common configuration and structure for blocking the B-light are applied to the R pixel unit 10A-R and the G pixel unit 10A-G.

However, for example, if only materials are provided, it can be considered that a different light blocking configuration is applied to each of the R pixel unit 10A-R, the G pixel unit 10A-G, and the B pixel unit 10A-B. For example, in the R pixel unit 10A-R, the planarization layer and/or the window layer made of a material which transmits only the R light and blocks the G light and the B light is formed. Likewise, in the G pixel unit 10A-G, the planarization layer and/or the window layer made of a material which transmits only the G light and blocks the R light and the B light is formed. In addition, in the B pixel unit 10A-B, the planarization layer and/or the window layer made of a material which transmits only the B light and blocks the R light and the G light is formed.

Consequently, in the embodiment of the invention, in the case where the pixel units which radiates the light of the plurality of different colors are provided, the insulation layer capable of blocking or attenuating the light of at least one specific color is provided in the pixel unit which radiates light other than the light of the one specific color.

Further, the layered structure, which can be applied to the organic EL panel, is not limited to the drawings given hitherto. Accordingly, even the insulation layer, which blocks or attenuates the light of one specific color, is not limited to the planarization layer and the window layer exemplified hitherto.

The present application contains subject matter related to that disclosed in Japanese Priority Patent Application JP 2009-220504 filed in the Japan Patent Office on Sep. 25, 2009, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A display apparatus comprising:
a pixel array that has pixel units arranged in a matrix on the basis of a predetermined array pattern, each pixel unit having a light emitting element formed therein and having a structure configured to emit light generated from the light emitting element,
wherein in the structure of the pixel unit, a photodetection element, which allows current to flow in response to received light, is provided to correspond to an inner area of a light emitting layer which forms the light emitting element, and
wherein the pixel unit has a light incidence structure configured to allow the light, which is generated from the light emitting element, to be incident to the photodetection element.

2. The display apparatus according to claim 1,
wherein the light emitting element includes the light emitting layer, a semi-reflective film which is formed on the light emitting layer, and a reflective film which is formed below the light emitting layer, and
wherein a distance from a light emission center of the light emitting layer to the semi-reflective film and a distance from the light emission center of the light emitting layer to the reflective film are respectively set to a length equal to an integer multiple of a wavelength of colored light which is emitted from the corresponding pixel unit.

3. The display apparatus according to claim 1 or 2, wherein the light incidence structure includes an opening portion formed on a position corresponding to the photodetection element in an anode metal, which has no optical transparency, as a reflective film formed below the light emitting layer forming the light emitting element.

4. The display apparatus according to claim 1 or 2, wherein the light incidence structure includes a solid anode metal, which has optical transparency, as a reflective film formed below the light emitting layer forming the light emitting element.

5. The display apparatus according to claim 1 or 2, wherein the light incidence structure includes a transparent anode metal, which has optical transparency and is formed on a position corresponding to the photodetection element, as an anode metal formed below the light emitting layer forming the light emitting element.

6. The display apparatus according to claim 2, wherein the light incidence structure further includes a window layer, which has optical transparency, formed below the light emitting layer forming the light emitting element.

7. The display apparatus according to claim 2,
wherein a black matrix is provided above the light emitting element of each pixel unit, and is formed as a black pattern which is formed so that a portion of the black pattern corresponding to an opening portion of the light emitting element is cut out, and
wherein the photodetection element is disposed below the black matrix.
